(19) United States
(12) Patent Application Publication
(10) Pub. No.: US 2005/0184326 A1
(43) Pub. Date: Aug. 25, 2005

(54) DEEP-TRENCH 1T-SRAM WITH BURIED OUT DIFFUSION WELL MERGED WITH AN ION IMPLANTATION WELL

(76) Inventor: Chun-Wen Cheng, Hsin-Chu City (TW)

Correspondence Address: NORTH AMERICA INTERNATIONAL PATENT OFFICE (NAIPC), P.O. BOX 506, MERRIFIELD, VA, 22116, US

(21) Appl. No.: 10/708,329

(22) Filed: Feb. 24, 2004

(51) Int. Cl. H01L 27/108

(52) U.S. Cl. 257/301

(57) ABSTRACT

A deep-trench 1T-SRAM memory cell is disclosed. The deep-trench 1T-SRAM memory cell includes a first conductivity type semiconductor substrate with a main surface. A second conductivity type ion implantation well with a well junction depth is located on the main surface. A gate dielectric layer is located on the ion implantation well. A gate is located on the gate dielectric layer. A heavily doped S/D region of the first conductivity type is disposed at one side of the gate in the ion implantation well. A lightly doped drain (LDD) region of the first conductivity type is disposed at the other side of the gate in the ion implantation well. A deep trench capacitor vertically extends into the main surface through the well junction depth of the ion implantation well to a pre-selected depth. The deep trench capacitor, which is fabricated adjacent to the LDD region, comprises an ion out diffusion well of the second conductivity type that is formed at a lower portion of the deep trench capacitor and is merged with the ion implantation well. A polysilicon electrode pillar is electrically isolated from the LDD region, the ion implantation well, and the ion out diffusion well by a capacitor dielectric layer and a trench top insulation layer.

### BACKGROUND OF INVENTION

1. Field of the Invention

The present invention relates to the field of deep-trench semiconductor memory devices, and more particularly, to a deep-trench one-transistor static random access memory (1T-SRAM) device and fabrication method thereof.

2. Description of the Prior Art

Semiconductor memory devices such as random access memory (RAM) devices typically include a number of memory cells coupled to at least one bit line. The memory cells often include at least one storage device, storage node, and pass gate transistor. Generally, in a static random access memory (SRAM) cell, two storage devices such as drive transistors are coupled between two pass gate transistors, and a bit line is coupled to each of the pass gate transistors. Thus, each memory cell is often located between two bit lines. The pass gate transistors (e.g., transfer gates) have gate electrodes that are coupled to word lines. A signal such as an address or select signal is provided on the word line associated with the memory cell to select or access a particular memory cell. Once the memory cell is selected via the word line, the memory cell can be read or written to through the pass gate transistors via the bit lines.

For system-on-chip (SoC) designers, memory-intensive applications in communications, graphics and personal electronics continue to accelerate the need for larger, faster embedded memory arrays in more complex SoC devices. Already, the memory content of typical SoCs has grown to replace logic as the largest component of these highly integrated devices and memory content will heavily dominate logic within a few years. Accordingly, embedded memory continues to exert the largest influence on SoC yield, cost, speed and reliability. By taking advantage of evolutionary trends in memory technology, however, designers can substantially improve cost, quality and performance of SoCs comprising great numbers of large memory blocks.

As technology advances, memory cell size has steadily decreased so more memory cells can be located on a single semiconductor substrate. Additionally, power supply has decreased. The decreased memory cell size and power supply reduces the amount of charge stored at each of the storage nodes. The trend of decreasing charge storage per node makes the memory cell more susceptible to charge loss due to parasitic leakage problems. In 1999, MoSys, Inc. (founded in 1991) announced a high performance, high-density, and cost-effective RAM architecture known as “1T-SRAM” technology, which uses a single transistor cell to achieve its exceptional density while maintaining the refresh-free interface and low latency random memory access cycle time associated with traditional six-transistor SRAM cells.

Embedded 1T-SRAM allows designers to get beyond the density limits of six-transistor SRAMs; it also reduces much of the circuit complexity and extra cost associated with using embedded DRAM. 1T-SRAM devices can be fabricated in either pure logic or embedded memory processes using as little as one ninth of the area of traditional six-transistor SRAM cores. In addition to the exceptional performance and density, this technology offers dramatic power consumption savings by using under a quarter of the power of traditional SRAM memories. Some disclosures regarding the above-said 1T-SRAM technology may be found in U.S. Pat. No. 6,028,804, entitled “Method and apparatus for 1T-SRAM compatible memory” or in U.S. Pat. No. 6,573,548, entitled “DRAM cell having a capacitor structure fabricated partially in a cavity and method for operating same”, which are incorporated herein by reference.

However, the above-said 1T-SRAM has the following drawbacks. First, each single memory cell of such 1T-SRAM memory still takes a chip surface area of about 0.5˜0.6 μm², even fabricated by using state-of-the-art semiconductor manufacturing process. The fabrication cost for such prior art 1T-SRAM is still high (about 4% higher than standard logic process). Furthermore, only small capacitance gain (about 3˜7 fF) is benefited from the above-said 1T-SRAM technology. Moreover, the above-said 1T-SRAM technology has severe isolation problem between two neighboring capacitors.

### SUMMARY OF INVENTION

Accordingly, the primary object of the present invention is to provide a deep-trench 1T-SRAM and logic-compatible manufacturing method thereof to solve the above-mentioned problems.

According to the claimed invention, a deep-trench 1T-SRAM memory cell is disclosed. The deep-trench 1T-SRAM memory cell includes a first conductivity type semiconductor substrate with a main surface. A second conductivity type ion implantation well with a well junction depth is located on the main surface. A gate dielectric layer is located on the ion implantation well. A gate is located on the gate dielectric layer. A heavily doped S/D region of the first conductivity type is disposed at one side of the gate in the ion implantation well. A lightly doped drain (LDD) region of the first conductivity type is disposed at the other side of the gate in the ion implantation well. A deep trench capacitor vertically extends into the main surface through the well junction depth of the ion implantation well to a pre-selected depth. The deep trench capacitor, which is fabricated adjacent to the LDD region, comprises an ion out diffusion well of the second conductivity type that is formed at a lower portion of the deep trench capacitor and is merged with the ion implantation well. A polysilicon electrode pillar is electrically isolated from the LDD region, the ion implantation well, and the ion out diffusion well by a capacitor dielectric layer and a trench top insulation layer.

In one aspect of the present invention, the deep-trench 1T-SRAM memory cell has a buried N⁺ out diffusion well that is merged with the ion implantation well formed on the main surface of the substrate. The buried N⁺ out diffusion well and the ion implantation well serve as a capacitor plate when in operation, thereby achieving higher capacitance and lower leakage characteristics.

It is to be understood that both the foregoing general description and the following detailed description are exemplary, but are not restrictive, of the invention. Other objects, advantages, and novel features of the claimed invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic cross-sectional diagram illustrating the substrate or memory chip after the deep trench etching according to the preferred embodiment of this invention;

FIG. 2 is a schematic cross-sectional diagram illustrating the substrate or memory chip after forming the buried N⁺ out diffusion well according to the preferred embodiment of this invention;

FIG. 3 is a schematic cross-sectional diagram illustrating the substrate or memory chip after the formation of the capacitor dielectric layer and the polysilicon layer of the deep trench capacitors according to the preferred embodiment of this invention;

FIG. 4 is a schematic cross-sectional diagram illustrating the substrate or memory chip after the formation of the deep trench capacitors according to the preferred embodiment of this invention;

FIGS. 5˜7 are schematic cross-sectional diagrams illustrating the active area definition and STI formation according to the preferred embodiment of this invention;

FIG. 8 is a schematic cross-sectional diagram illustrating the substrate or memory chip after logic gate/PLDD/source/drain formation according to the preferred embodiment of this invention; and

FIG. 9 is a schematic cross-sectional diagram illustrating the substrate or memory chip after share contact and bit line contact formation according to the preferred embodiment of this invention.

### DETAILED DESCRIPTION

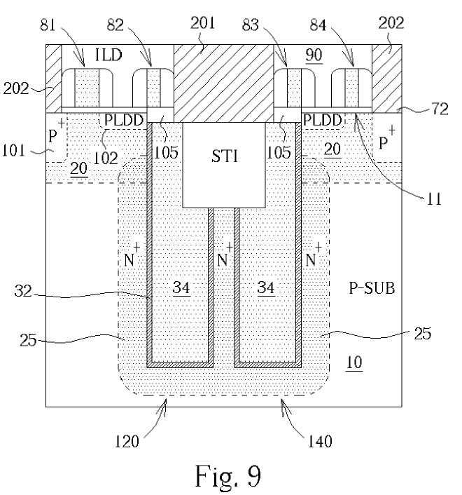

Please refer to FIG. 9. FIG. 9 is a schematic cross-sectional diagram illustrating the structure of deep-trench capacitor 1T-SRAM according to one preferred embodiment of the present invention. As shown in FIG. 9, the deep-trench capacitor 1T-SRAM cell comprises a first conductivity type semiconductor substrate 10 having a main surface 11, a second conductivity type ion implantation well 20 with a pre-determined well junction depth, say 1 micrometer, located on the main surface 11 of the semiconductor substrate 10, and a gate dielectric layer 72 formed on the ion implantation well 20. A conductive gate 81 is disposed on the gate dielectric layer 72. A first conductivity type heavily doped region 101 is disposed in the ion implantation well 20 at one side of the conductive gate 81. A lightly doped drain (LDD) region 102 of first conductivity type is disposed at the other side of the conductive gate 81 opposite to the heavily doped region 101 in the ion implantation well 20. A deep trench capacitor 120, which is formed in a deep trench that is etched vertically into the main surface 11 of the semiconductor substrate 10 through the well junction depth of the ion implantation well 20, is fabricated adjacent to the LDD region 102. As specifically indicated, the deep trench capacitor 120 vertically extends down into the semiconductor substrate 10 to a depth of about 3˜5 micrometers from the main surface 11.

The deep trench capacitor 120 comprises a buried ion out diffusion well 25 of second conductivity type that is formed at a lower portion of the deep trench capacitor 120. This invention features that a top portion of the buried ion out diffusion well 25 is merged with the ion implantation well 20. The deep trench capacitor 120 further comprises a polysilicon electrode pillar 34 that is electrically isolated from the LDD region 102, the ion implantation well 20, and the buried ion out diffusion well 25 by a node/capacitor dielectric film 32 and an STI layer. A trench top insulation layer 105 having a thickness of about 200˜400 angstroms is disposed atop the polysilicon electrode pillar 34.

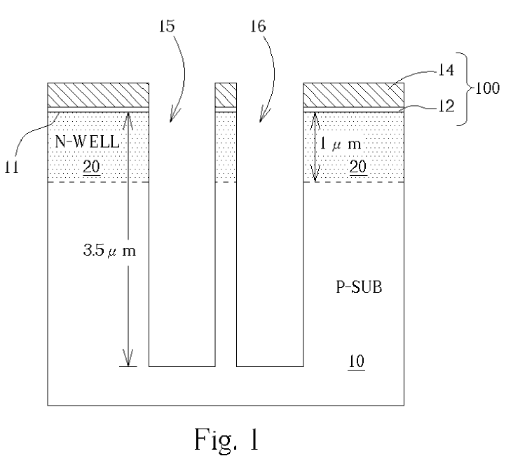

An exemplary method for fabricating the deep-trench capacitor 1T-SRAM according to one preferred embodiment of the present invention will be explained in detail with reference to FIGS. 1˜9.

As shown in FIG. 1, a substrate 10 such as a P type doped silicon substrate is provided. An N well 20 is formed on a main surface 11 of the substrate 10. The well junction depth of the N well 20 is about 0.5˜1.5 micrometers, preferably about 1 micrometer. A pad layer 100 comprising a pad oxide layer 12 and a pad nitride layer 14 is deposited over the main surface of the substrate 10. Deep trenches 15 and 16 are then etched into the main surface 11 of the substrate 10 through the well junction depth of the N well 20 to a depth of about 3˜5 micrometers, preferably 3.5 micrometers, by using any suitable methods such as conventional lithographic process and dry etching process known in the art.

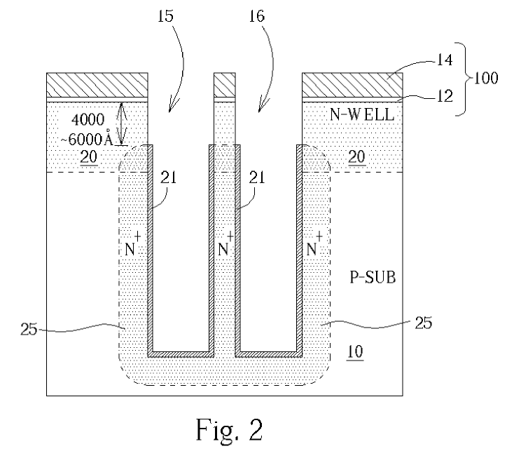

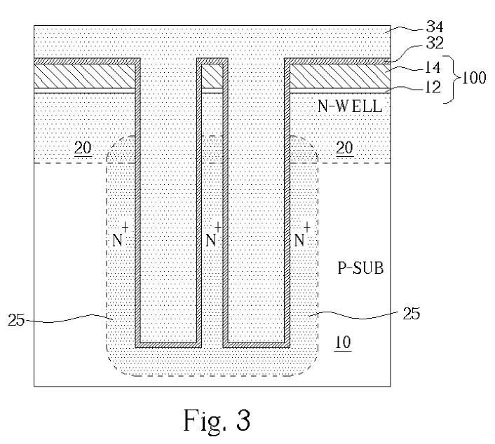

As shown in FIG. 2, a high concentration N type dopants are implanted into the deep trenches 15 and 16 on their lower sidewall below the main surface 11 of about 4000˜6000 angstroms as well as their bottom surface, thereby forming a buried N⁺ out diffusion well. To accomplish such doping, for example, a thin arsenic silicate glass (ASG) film 21 is first deposited on interior surface of the deep trenches 15 and 16. A photoresist layer (not shown) is deposited on the ASG film 21 and fills the deep trenches 15 and 16. The photoresist layer is then etched back selective to the underlying ASG film 21 to a surface level about 4000˜6000 angstroms below the main surface 11 of the substrate 10. The exposed ASG film 21 is then removed. After stripping the remaining photoresist layer, a thermal process such as RTP is carried out to drive in the dopants (i.e., As) from the ASG film 21 into the substrate 10. Subsequently, the ASG film 21 is removed. In another case, a heavily doped polysilicon layer may be used. It is to be understood that if the heavily doped polysilicon layer is used, it may be left in place after out diffusion. It is specifically indicated in FIG. 2 that the top portion of the buried N⁺ out diffusion well 25 formed at the lower portion of the deep trenches 15 and 16 is merged with the N well 20.

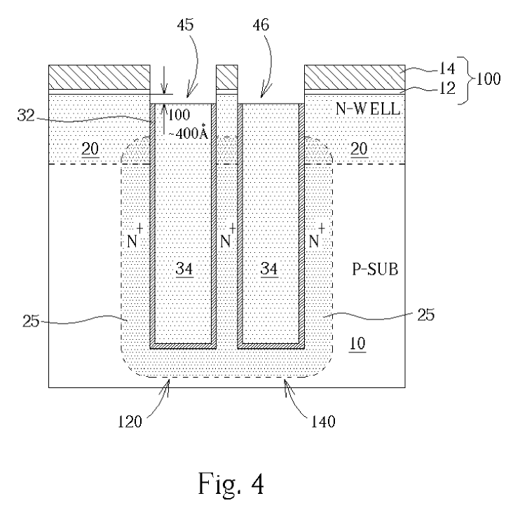

As shown in FIG. 3, a capacitor dielectric layer 32 is deposited on interior surface of the deep trenches 15 and 16, and also on the surface of the pad layer 100. In accordance with the preferred embodiment of the present invention, the capacitor dielectric layer 32 is an oxide-nitride-oxide (ONO) dielectric layer, but not limited thereto. An N type doped polysilicon layer 34 is then deposited on the capacitor dielectric layer 32 and fills the deep trenches 15 and 16.

Subsequently, as shown in FIG. 4, the polysilicon layer 34 is etched back to a pre-selected surface level inside the deep trenches 15 and 16 about 100˜400 angstroms, preferably 200˜300 angstroms, below the main surface 11 of the substrate 10. Thereafter, the exposed capacitor dielectric layer 32 that is not covered by the polysilicon layer 34 is etched away by using any suitable methods such as wet etching, thereby forming deep trench capacitors 120 and 140. At this time, recess openings 45 and 46 are formed at each top of the deep trenches 15 and 16.

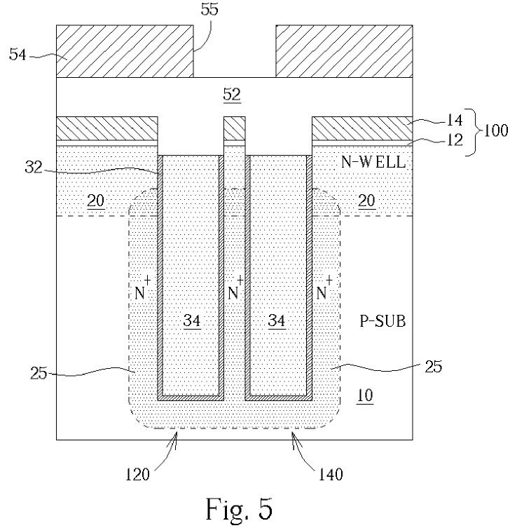

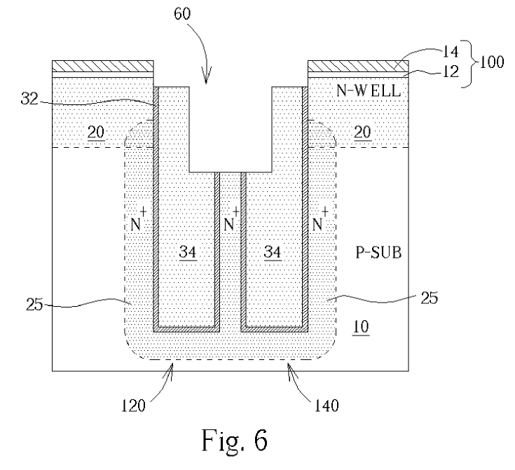

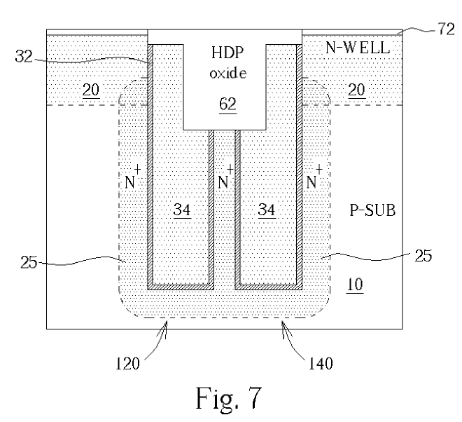

As shown in FIG. 5, logic shallow trench isolation (STI) module is then carried out. In accordance with the preferred embodiment of this invention, a dielectric layer 52 such as borosilicate glass (BSG) is deposited on the substrate 10 and fills the recess openings 45 and 46. A photoresist layer 54 is then formed on the dielectric layer 52. The photoresist layer 54, which is patterned by using a conventional lithographic process, has an opening 55 defining STI regions to be etched into the substrate 10. In another preferred embodiment, an anti-reflection coating (ARC) layer may be disposed between the photoresist layer 54 and the dielectric layer 52, but this is not germane to the invention. Then, using the photoresist layer 54 and the dielectric layer 52 as an etching mask, an an isotropic dry etching is carried out to etch the dielectric layer 52, the pad layer 100, the substrate 10, a portion of the doped polysilicon layer 34 and capacitor dielectric layer 32 through the opening 55. As shown in FIG. 6, an STI recess 60 is formed after removing the remaining photoresist layer 54 and dielectric layer 52.

As shown in FIG. 7, a high-density plasma chemical vapor deposition (HDPCVD) is carried out to deposit an HDP oxide layer 62 on the substrate 10 and fills the STI recess 60. A conventional chemical mechanical polishing (CMP) is then performed to polish the HDP oxide layer 62 using the pad layer 100 as a polishing stop layer, thereby obtaining a planar topography of the substrate 10. The remaining pad layer 100 is stripped off. A standard logic process is then carried out. A new gate oxide layer 72 having a thickness of about 10˜100 angstroms is grown on the exposed substrate surface by using a thermal oxidation method.

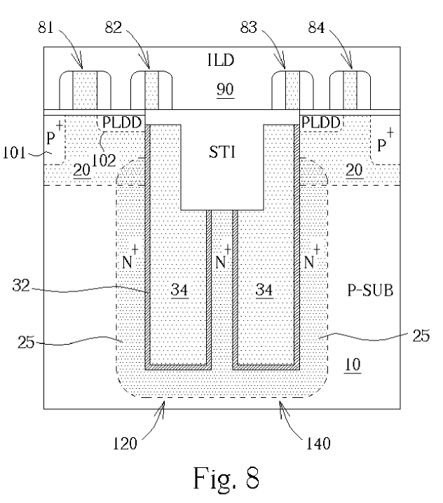

As shown in FIG. 8, a polysilicon layer (not shown) is deposited on the gate oxide layer 72 and then patterned into a plurality of gate structures 81, 82, 83, and 84 by using a conventional lithographic process and dry etching process, wherein the gate 81 is an access gate of the deep trench capacitor 120, the gate 84 is an access gate of the deep trench capacitor 140, the gates 82 and 83 are passing gate lines that are isolated from the underlying deep trench capacitors 120 and 140 by a trench top insulation layer 105. Using the gate structures 81, 82, 83, and 84 as an implantation mask, a P-type lightly doped drain/source (LDD or LDS) ion implantation process is performed to form PLDD 102 at a side of respective gates 81 and 84 in the N well 20, which is adjacent to the deep trench capacitor thereof. After forming logic spacers on sidewalls of the gates, and using a suitable mask, P⁺ doping is then carried out to form a P⁺ source/drain region 101 at the other side of the gates 81 and 84 in the N well 20. Through the P channel underneath the gate 81, data may be read from or written into the deep trench capacitor 120. Through the P channel underneath the gate 84, data may be read from or written into the deep trench capacitor 140. Subsequently, an inter-layer dielectric (ILD) layer 90 is deposited on the substrate 10. The ILD layer 90 covers the gates and fills the inter spacing between gates. The ILD layer 90 may be BSG, BPSG, silicon dioxide, or the like, which are not germane to this invention.

As shown in FIG. 9, a conventional lithographic process and dry etching process is performed to form a share contact opening in the ILD layer 90. The share contact opening exposes a portion of the top surface of the polysilicon electrode pillar 34 of each of the deep trench capacitors 120 and 140. Conductive material such as tungsten or the like is the deposited into the share contact opening so as to form a share contact plug 201 that penetrates through the trench top insulation layer 105 to the polysilicon electrode pillar 34. Bit line contacts 202 are also formed in the ILD layer 90 to electrically connect the P⁺ source/drain region 101 to a bit line (not shown).

In operation, taking the left 1T-SRAM cell of FIG. 9 as an example, the gate 81 is biased to a gate voltage such that a horizontal P channel under the gate 81 is turned on. The P⁺ source/drain region 101 is biased to a bit line voltage. A negative voltage is applied to the polysilicon electrode pillar 34 via the share contact plug 201 and thus induces a vertical P channel (not explicitly shown) between the PLDD 102 and the buried N⁺ out diffusion well 25. Based on the above-mentioned conditions, holes drift from the P⁺ source/drain region 101, through the turned-on horizontal P channel under the gate 81, the PLDD 102, the induced vertical P channel, then to the buried N⁺ out diffusion well 25.

It is understood that, while the detailed drawings and specific examples given describe the preferred exemplary embodiment of the present invention, it is for the purpose of illustration only. The device and method of the invention is not limited to the precise details, geometries, dimensions, and conditions disclosed. For example, although particular layers are described as being particular sizes, other sizes could be utilized. Further, although polysilicon is used as exemplary conductive material, other conductive materials may be utilized. Those skilled in the art will readily observe that numerous modifications and alterations of the present invention may be made while retaining the teachings of the invention. Accordingly, the above disclosure should be construed as limited only by the metes and bounds of the appended claims.

1. A deep trench capacitor memory cell, comprising:
a first conductivity type semiconductor substrate with a main surface;
a second conductivity type ion implantation well with a well junction depth located on said main surface;
a gate dielectric layer located on said ion implantation well;
a gate located on said gate dielectric layer;
a heavily doped S/D region of said first conductivity type disposed at one side of said gate in said ion implantation well;
a lightly doped drain (LDD) region of said first conductivity type disposed at the other side of said gate in said ion implantation well; and
a deep trench capacitor vertically extending into said main surface through said well junction depth of said ion implantation well to a pre-selected depth, wherein said deep trench capacitor, which is fabricated adjacent to said LDD region, comprises an ion out diffusion well of said second conductivity type that is formed at a lower portion of said deep trench capacitor and is merged with said ion implantation well, and a conductive electrode pillar electrically isolated from said LDD region, said ion implantation well, and said ion out diffusion well by a capacitor dielectric layer and a trench top insulation layer.

2. The deep trench capacitor memory cell according to claim 1 wherein said first conductivity type is P type, and said second conductivity type is N type.

3. The deep trench capacitor memory cell according to claim 1 wherein said ion out diffusion well has a top end located a depth of about 4000˜6000 angstroms below said main surface of said substrate.

4. The deep trench capacitor memory cell according to claim 1 wherein said deep trench capacitor vertically extends into said main surface through said well junction depth of said ion implantation well to a depth that is deeper than 3 micrometers.

5. The deep trench capacitor memory cell according to claim 1 wherein said capacitor dielectric layer is an oxide-nitride-oxide (ONO) dielectric layer.

6. The deep trench capacitor memory cell according to claim 1 wherein said trench top insulation layer is made of silicon oxide.

7. The deep trench capacitor memory cell according to claim 6 wherein said trench top insulation layer is disposed atop said conductive electrode pillar and has thickness of about 100˜400 angstroms.

8. A deep-trench 1T-SRAM device, comprising:
a PMOS transistor formed on an N-type ion implantation well, wherein said N-type ion implantation well is formed on a surface of a P-type semiconductor substrate, wherein said PMOS transistor comprises a gate located on said N-type ion implantation well, a gate dielectric layer interposed between said gate and said N-type ion implantation well, a P⁺ source/drain region disposed at one side of said gate in said N-type ion implantation well, and a P-type lightly doped region (LDD) region disposed in said N-type ion implantation well at the other side of said gate that is opposite to said P⁺ source/drain region; and
a deep trench capacitor vertically extending into said surface of said semiconductor substrate and penetrating through said well junction depth of said ion implantation well to a pre-selected depth, wherein said deep trench capacitor, which is fabricated adjacent to said P-type LDD region, comprises an N⁺ ion out diffusion well that is formed at a lower portion of said deep trench capacitor and is merged with said N-type ion implantation well, and a conductive electrode pillar electrically isolated from said P-type LDD region, said N-type ion implantation well, and said N⁺ ion out diffusion well.

9. The deep-trench 1T-SRAM device according to claim 8 wherein a trench top insulation layer is disposed atop said conductive electrode pillar.

10. The deep-trench 1T-SRAM device according to claim 9 wherein a share contact plug penetrates through said trench top insulation layer and is electrically connected to said conductive electrode pillar.

11. The deep-trench 1T-SRAM device according to claim 9 wherein said trench top insulation layer is made of silicon oxide.

12. The deep-trench 1T-SRAM device according to claim 11 wherein said trench top insulation layer has a thickness of about 100˜400 angstroms.

13. The deep-trench 1T-SRAM device according to claim 8 wherein said capacitor dielectric layer is an oxide-nitride-oxide (ONO) dielectric layer.

14. The deep-trench 1T-SRAM device according to claim 8 wherein said deep trench capacitor vertically extends into said surface through said well junction depth of said ion implantation well to a depth that is deeper than 3 micrometers.
